(19) United States
(12) Patent Application Publication
(10) Pub. No.: US 2024/0050986 A1
(43) Pub. Date: Feb. 15, 2024

(54) ULTRASOUND TRANSMITTER

(71) Applicant: University of Leeds, Leeds, Yorkshire (GB)

(72) Inventors: Steven Freear, Leeds, Yorkshire (GB); David Matthew Joseph Cowell, Leeds, Yorkshire (GB); Thomas Michael Carpenter, Leeds, Yorkshire (GB)

(73) Assignee: University of Leeds, Leeds, Yorkshire (GB)

(21) Appl. No.: 18/266,564

(22) PCT Filed: Dec. 9, 2021
(86) PCT No.: PCT/GB2021/053227

§ 371 Date: Jun. 9, 2023

(30) Foreign Application Priority Data
Nov. 12, 2020 (GB) 2019565.7

(51) Int. Cl. B06B 1/02; H03F 3/217

(52) U.S. Cl. CPC B06B 1/0215; H03F 3/2173; H03F 2200/451

(57) ABSTRACT

Examples provide a multilevel switched-mode ultrasound transmitter comprising a first push-pull transistor arrangement comprising first and second drive transistors, third and fourth additional switched transistors, each arranged as a bidirectional load switch with a one of the first and second drive transistors, wherein the first drive transistor and associated third additional switched transistor operate in series as a first arm of the first push-pull transistor arrangement, and the second drive transistor and associated fourth additional switched transistor operate in series as a second arm of the first push-pull transistor arrangement, wherein each arm is coupled between a respective polarity instance of a first bipolar drive voltage supply and a common output.

### BACKGROUND

Ultrasound transmitter design is an important consideration in any ultrasound platform, for both commercial and research applications. Different modalities of ultrasound present differing requirements on the transmit drive circuitry, be that the high power Continuous Wave (CW) requirements for High-Intensity Focused Ultrasound (HIFU) therapy, or the high frequency drive capabilities required for High-Frequency Ultrasound (HFUS) applications. Current transmitters are typically limited to only a small subset of applications, with trade-offs between frequency, power and bandwidth. A unified transmitter architecture capable of working over a wide range of ultrasound modalities, both at very high frequencies, and at high powers, would allow for ultrasound devices to be more generally useful, with broader functionality.

### SUMMARY OF INVENTION

A switched-mode ultrasound transmitter topology is disclosed. The disclosed topology requires no transformer or matching components and provides full push pull capabilities to any number of specified voltage levels. The disclosed topology may utilise Gallium-Nitride (GaN) transistor technology to achieve both high speed switching and high power handling. Examples may be used for multiple ultrasound modalities. For example, at diagnostic imaging frequencies using Harmonic-Reduction Pulse-Width Modulation (HRPWM) for linear amplitude control, for HFUS with bipolar drive capabilities up to multi-hundred MHz (e.g. 100 MHz), and for HIFU therapy driving a large single element transducer with relatively high power output (e.g. 50 W average power continuous wave (CW) for multiple seconds).

### BRIEF DESCRIPTION OF THE DRAWINGS

Further details, aspects, examples and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 shows an example circuit schematic diagram of an all NMOS ultrasound push-pull transmitter bridge topology base portion according to an embodiment of the present disclosure;

FIG. 2 shows an example circuit schematic diagram of an ultrasound push-pull transmitter bridge topology of FIG. 1 used in a multilevel ultrasound transmitter according to an embodiment of the present disclosure;

FIG. 3 shows an example circuit schematic diagram of an alternative front end arrangement of a multilevel ultrasound transmitter according to an embodiment of the present disclosure;

FIG. 4 shows an example circuit schematic diagram of an all PMOS arrangement of a multilevel ultrasound transmitter according to an embodiment of the present disclosure;

FIG. 5 shows an example circuit schematic diagram of gate drive circuitry for use in a multilevel ultrasound transmitter according to an NMOS embodiment of the present disclosure;

### DETAILED DESCRIPTION

In the following description, for purposes of explanation, numerous specific details of certain examples are set forth. Reference in the specification to “an example” or similar language means that a particular feature, structure, or characteristic described in connection with the example is included in at least that example, but not necessarily in other examples.

Ultrasound transmitter design is an important consideration in any ultrasound platform, for both commercial and research applications. The quality of an imaging technique is not only limited by the performance of the transducer and receivers, but also by the ability to generate ultrasound transmissions with the desired frequency, bandwidth, and envelope. Different modalities of ultrasound present differing requirements on the transmit drive circuitry, be that the high power (>10 W) Continuous Wave (CW) requirements for High-Intensity Focused Ultrasound (HIFU) therapy, or high frequency drive capabilities (>30 MHz) for High-Frequency Ultrasound (HFUS) applications (such as bio-microscopy for small animals, or ophthalmology). The typical existing transmitter technologies available tend to lend themselves to only a small subset of applications, with trade-offs between frequency, power and bandwidth. Therefore, the present disclosure provides a unified transmitter architecture capable of working over a wide range of ultrasound modalities, both at very high frequencies, and at high powers, that would allow for ultrasound devices to be more generally useful, with broader functionality.

Existing integrated switched ultrasound transmitters tend to top out at around 20 MHz to 30 MHz maximum operating frequency, which restricts their usefulness in HFUS applications. In these cases, high frequency transmission is generally achieved using either dedicated test equipment or pulse generator circuitry. For example, by using test equipment such as power amplifiers or pulse generators. However, this approach limits usage to single-element transmission, or requires multiple pieces of test equipment to be deployed, which is costly (in value, size, power usage, etc). Alternatively, dedicated high speed pulse generators may be built, such as carefully tuned impulse circuitry, or simple bipolar pulse generators, but these are tuned to a specific transducer and frequency, so are not useful as a general purpose ultrasound transmitter.

Meanwhile, driving large single element HIFU transducers would require a system with transmitters capable of delivering continuous output powers of >>10 W into loads of <50Ω for several seconds. This is beyond the capabilities of typical existing ultrasound transmitter topologies due to thermal limitations, and so would require either a dedicated HIFU system to control, or a high power amplifier which may require the use of lossy impedance matching networks.

Accordingly, examples of the disclosure provide transmitters capable of delivering higher currents, so that low impedance transducers may be driven without using a matching network, and dynamic switching losses in switched mode transmitters may be reduced for lower voltages.

Furthermore, applications such as Passive Acoustic Mapping (PAM), which is a passive imaging modality utilised in conjunction with a HIFU therapy for guidance and monitoring, could also benefit from a unified transmit architecture. In order to avoid interference between the imaging and therapy modes in PAM systems, the two modalities are typically interleaved, which requires careful synchronisation. However, synchronisation can be simplified by using a single system for both modalities, enabled by providing an ultrasound transmitter topology capable of driving high power transducers, and at high frequency, where required.

Ideally, an ultrasound device would be driven by a linear Power Amplifier. Linear Power Amplifiers (PAs), such as class A and B designs, make use of a transistor elements operating in their linear region, typically controlled via a Digital to Analogue Converter (DAC), and typically driving a transformer to increase the output drive voltage. For high power or CW applications, these linear PAs must be physically large to allow for large cooling systems due to the inefficient nature of these amplifiers (e.g., because they are operating only in the linear region of the amplifier, which is only a small portion of the overall characteristic response) particularly when amplitude control is required.

As a more efficient alternative to linear amplifiers, switched-mode transmitters for ultrasound were developed. Switched circuits use a series of discrete voltage levels to approximate an analogue waveform using a stepped waveform to drive the ultrasound device coupled to the transmitter. These allow for much higher efficiency and speed than linear PAs. There are many different forms of switched mode transmitter, from class D, DE and similar PAs, to multilevel designs for diagnostic ultrasound frequencies to unipolar pulse generators designed to produce wide bandwidth transducer response. However, none of the switched-mode transmitter topologies to date has provided sufficiently symmetrical output (i.e. symmetrical on both positive and negative supplies of a bipolar power supply) and very wide bandwidth operation or overall implementation efficiency (i.e. sufficiently low complexity design and/or part count, or the like).

For example, class-DE switched mode PAs can be used to drive ultrasound transducers, particularly in HIFU applications. These class-DE switched mode PA circuits are significantly more efficient than linear PAs and can be more compact due to reduced cooling requirements. However, in order to approximate a linear output, additional filtering and matching circuitry is required on the output, which limits the useable bandwidth of the transmitter.

While switched circuits have many benefits from a circuit implementation standpoint, as a consequence of the limited number of voltage levels used by the circuit to generate the output driving waveforms (e.g. in the order of 5 levels or so), the output waveforms generated by such circuits introduce unwanted harmonics into the waveform, particularly at the third and fifth harmonic. This can be especially problematic for particular use-cases of ultrasound transmitters, such as harmonic imaging, whereby the second, or higher order harmonic echo responses are used for image formation, or for HIFU techniques where the transducers are particularly resonant at these harmonics. Thus, improvements to help reduce harmonics are desirable.

It is possible to reduce harmonic distortion by non-structural means, for example, the harmonic output of multilevel switched-mode ultrasound transmitters can be reduced through careful design of the transmit waveforms. One example of this approach is known as Harmonic-Reduction Pulse-Width Modulation (HRPWM), and it has been previously shown to allow amplitude control with cancellation of the third harmonic and partial cancellation of the fifth harmonic, whilst other waveform design techniques using multilevel converters can produce gaussian or reduced harmonic waveforms. HRPWM techniques have also been demonstrated for HIFU applications, showing the technique can be used in multiple modalities. However, alternative or additional structural changes to an ultrasound transmitter design may also be of use, and examples of the present disclosure provide such structural improvements to ultrasound transmitter designs.

Some known switched-mode ultrasound transmitters use a bipolar half-bridge topology. These half-bridges use a mixture of PMOS and NMOS transistors in a pseudo-Complementary Metal Oxide Semiconductor (CMOS) push-pull design for simplified gate control—all gates in this sort of topology are referenced to fixed supply rails. However, use of NMOS transistors provide faster switching and lower losses than PMOS transistors of comparable size. Therefore, in order to achieve symmetric drive strengths, such circuit must be designed to use either larger or multiple parallel PMOS devices (compared to the NMOS devices), resulting in a number of problems, including higher relative circuit complexity or cost, and slower switching speeds. Accordingly, embodiments of the present disclosure use an all-NMOS topology to allow for higher performance transmitters. In some embodiments, in order to achieve (even) higher switching speeds and performance, it is proposed to use high mobility transistor devices, for example GaN transistors as an alternative to silicon Metal-Oxide-Semiconductor Field Effect Transistor (MOSFET) technology. GaN is an alternate semiconductor technology which has seen a lot of interest and development over the last decade, largely in relation to electric car applications. The technology generally provides higher switching speeds and higher power handling capabilities than silicon transistors. GaN is however primarily designed in NMOS configurations as current GaN PMOS devices suffer from poor switching performance, therefore in some embodiments, the use of an all-NMOS topology would still be beneficial for examples using GaN devices throughout.

Several all-NMOS transmitters have been demonstrated. However, these typically use a centre-tapped transformer on the output. By connecting the centre-tap of the transformer to a supply rail it is possible to reference both switches to the system ground level allowing for simple gate control. When implementing these all-NMOS transmitters using GaN devices throughout, for high speed and improved power handling capabilities, the power handling of miniature transformers is however limited which is problematic for CW applications, for example because the use of transformers limits the output bandwidth of the transmitter. Multiple transformer windings would also be required to extend such a transmitter design to become a multilevel design (=more than 3 levels, more typically 5 or more) required for harmonic reduction and amplitude control techniques, placing further burden on the transformer design.

Accordingly, the present disclosure proposes a base design of a multilevel switched-mode ultrasound transmitter that uses a modified push-pull arrangement that utilises an additional switched transistor in each arm of the half-bridge arrangement, in addition to the main drive transistor, where the additional switched transistor is arranged as a bidirectional load switch (where being arranged as a bidirectional load switch means the transistor is arranged so that a gate voltage applied to the additional switched transistor can control whether the diode allows the reverse current to flow or not, and hence can controllably prevent current flow through the drive transistor when reverse biased).

FIG. 1 shows this newly proposed ultrasound transmitter base push-pull transistor arrangement portion 100 in more detail. This figure shows the newly proposed ultrasound transmitter base push-pull transistor arrangement comprises a half bridge arrangement coupled across a pair of bipolar voltage supply rails—a positive supply voltage V_{P} 10 and a negative supply voltage V_{N} 12. These are referred to herein as respective polarity instance(s) of a bipolar drive voltage supply (this is because each supply provides two different supply voltages—positive and negative, and multiple different bipolar drive supply voltages may be used, as seen and described in detail below). The half bridge arrangement comprises two arms—in the figure, a top arm 20, and bottom arm 30, having a common output V_{XDR} 15. It will be appreciated that the terms top and bottom are arbitrary—in fact the only important factor to note is that one is coupled between the positive supply voltage V_{P} 10 and the common output V_{XDR} 15, and the other is coupled between the negative supply voltage V_{N} 12 and the common output V_{XDR} 15. Taking the top arm 20 first, the arm comprises a drive transistor 24, with associated gate drive voltage A_{P(X)} 25, and a second additional switched transistor 22, having an associated gate drive voltage A_{P(N)} 23. Note the inherent diode action of transistor 22 and 24 are arranged in reverse polarity to one another. For the corresponding bottom arm 30, the arm comprises a drive transistor 32, with associated gate drive voltage A_{N(N)} 33, and a second additional switched transistor 34, having an associated gate drive voltage A_{N(X)} 35. Note the inherent diode action of transistor 32 and 34 are also arranged in reverse polarity to one another. This inherent diode action may also be referred to as the ‘(intrinsic) body diode’, ‘parasitic diode’, or even ‘the diode like behaviour seen in some transistor types’ (e.g. in GaN devices).

From FIG. 1, it can be seen that the gate voltage (A_{N(X)} and A_{P(X)}) applied to transistors 24, 34 is relative to the common output V_{XDR} 15, and the gate voltage (A_{P(N)} and A_{N(N)}) applied to transistors 23, 33 is relative to the respective polarity instance of the bipolar power supply (i.e. bipolar drive voltage supply). The signals for the positive arm, 23, 25, may be controlled to switch respective transistors 22, 24 on or off simultaneously using any form of isolated gate drive, such as shown in FIG. 5. For the negative arm, similarly the gate drive signals, 33, 35, may be controlled together using isolated gate drive circuitry similar to FIG. 5 also.

As will now be appreciated by the skilled person, a half-bridge arrangement uses diode functions in series with the drive transistors in order to allow their use in providing multilevel voltage supplies, since otherwise the parasitic Field Effect transistor (FET) body diodes (i.e. inherent diode function) of the drive transistors would conduct when the FET is forced into reverse bias by switching to a higher magnitude voltage rail. However, use of plain diodes would prevent reverse conduction of the half-bridge, which would prevent the half-bridge from acting in a push-pull capacity (because each rail would be limited to only pulling outwards by the parasitic diodes). This would cause undesirable second harmonic distortion, increase total harmonic distortion, and a loss of amplitude control when using techniques such as HRPWM. The use of plain diodes would also limit the performance of the overall multilevel transmitter design, for example due to reverse recovery times and forward voltage drops across the parasitic diodes causing additional losses.

Therefore, the present disclosure replaces the use of plain diodes in the half-bridge with additional switched elements (i.e. suitably arranged and controlled active transistors). In this way, it is possible to increase the performance of the multilevel switched-mode ultrasound transmitter design. This is to say, for each arm, by connecting a second FET (e.g. 22 or 34) in place of a plain diode, with source and drain reversed compared to the main drive transistor (e.g. 24 or 32), the same level of reverse conduction protection is provided when the half-bridge is switched off. Crucially when switched on, unlike plain diodes, the new additional switched transistor in each arm allows for bidirectional conduction and provides a much lower power loss compared with a plain diode. Note, these additional switched transistors can either be connected in source-coupled configuration, or the drain-coupled configuration, dependent on the topology of the remainder of the transmitter circuit (e.g. use of NMOS/PMOS, etc).

This change to the overall topology produces a fully push-pull multilevel switched-mode ultrasound transmitter capable of driving complex loads and faithfully producing designed HRPWM waveforms. This change is well suited to implementation using GaN devices, which are naturally capable of providing high performance under both forward and reverse conduction. However, alternative examples may make use of other transistor technologies with inherent capabilities that are synergistic with this proposed design, such as Silicon NMOS, Silicon Carbide (another high-mobility semiconductor), and any future transistor technology yet to be created.

Furthermore, any number of arms of this base push-pull transistor arrangement can be implemented in a given design, so that any number of output voltage levels can be used/provided.

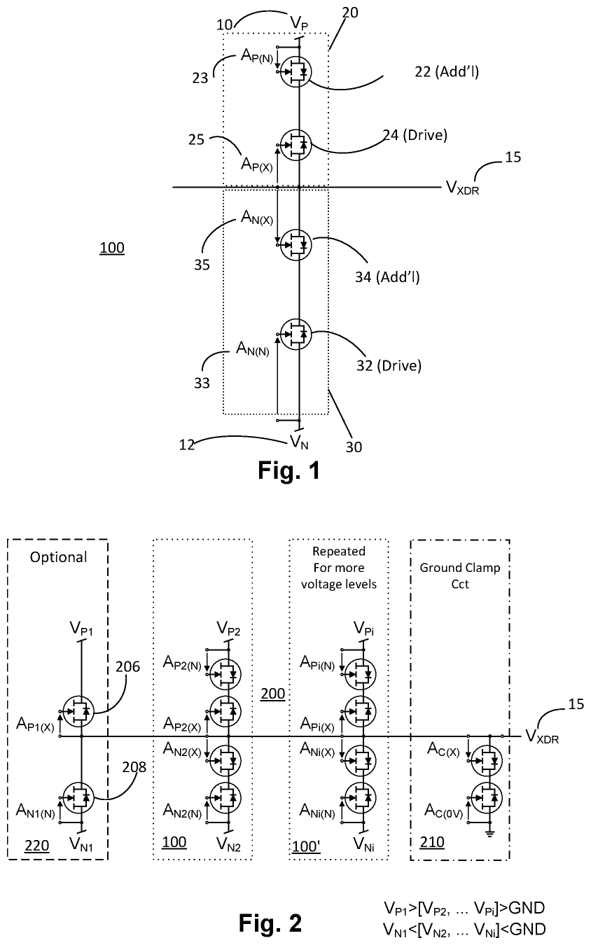

FIG. 2 shows an example circuit schematic diagram of an ultrasound push-pull transmitter bridge topology of FIG. 1 used in a multilevel ultrasound transmitter according to an embodiment of the present disclosure. In effect, FIG. 2 shows the complete generic topology 200 for implementing any multilevel ultrasound push-pull transmitter (7-level in this generic instance). The generic topology shown includes a first push-pull transistor arrangement 100 as per FIG. 1, a second push-pull transistor arrangement 100′, which is structurally the same as the first 100, but coupled across a different bipolar power supply V_{Pi}/V_{Ni} (of lower magnitude in this case, i.e. V_{P2}>V_{P1}, and V_{N2}>V_{Ni}). The circuit of FIG. 2 also shows a ground clamp circuit 210, which is effectively a single arm of the same half-bridge design (e.g. the same as arm 30 in FIG. 1), and clamps the mid-point output to ground, as well as an optional out rail bridge 220, which comprises a pair of single drive transistors, one per arm (top and bottom). In general terms, the generic topology 200 for a multilevel switched-mode ultrasound transmitter shown in FIG. 2 includes a bipolar outer voltage rail (+)V_{P1} and (−)V_{N1}, bipolar mid voltage rail (+)V_{P2} and (−)V_{N2}, (and any additional further voltage rails, as needed to power more output voltage levels) and a ground clamp circuit GND 210. The ground clamp circuit 210 ensures that one output of the transmitter is clamped to 0V, which may be useful in some implementations. For example, where a switched mode transmit waveform utilises a 0V level, or where the ultrasound transducers used have a capacitive impedance where they will remain at a given voltage after being driven at that voltage, so it is beneficial to apply a Return to Zero (RTZ) drive methodology (e.g. so that the starting state of the transducer is the same in each direction, each time it is driven, which improves consistency and symmetrical operation, or discharge any residual voltage on the transducer when switching from transmit to receive modes). The mid voltage rails, (+)V_{P2} and (−)V_{N2}, (and any further rails −(+)V_{Pi} and (−)V_{Ni}) and ground clamp 210, each use a drain coupled pair of GaN devices to drive to each rail. By setting a restriction that the bipolar mid voltage rails must be lower magnitude than the bipolar outer voltage rails, it is possible to simplify the outer rail bridge 220 to just two drive transistors, one to drive to each of (+)V_{P1} and (−)V_{N1}. This is because, during use, these two drive transistors should never be reverse biased, which is ensured by maintaining the stated relationship between the magnitudes of the respective positive and negative supplies rails.

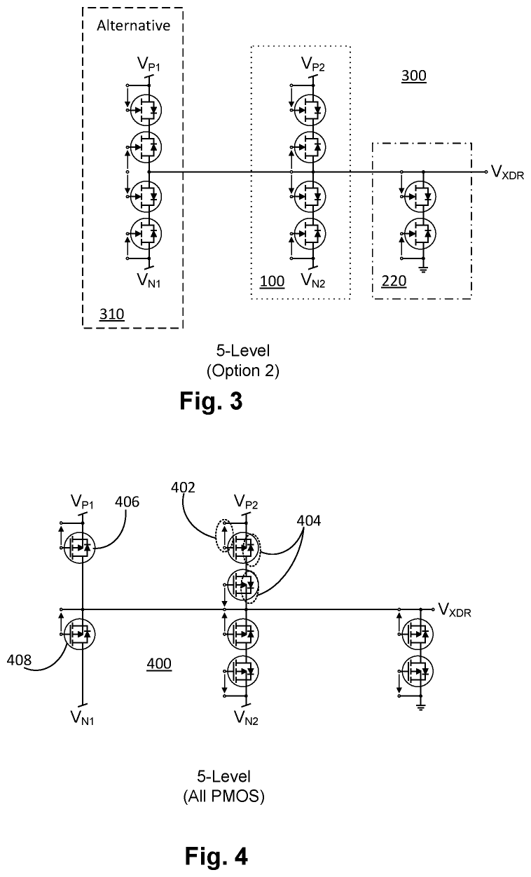

In an example of a simple implementation, the ultrasound transmitter may be a three level device, and only consist of the circuit of FIG. 1, with a ground clamp coupled between the common output and ground, and would equate to only items 100 and 220 of FIG. 3.

FIG. 3 shows an alternative front end arrangement of a multilevel ultrasound transmitter according to an embodiment of the present disclosure, in which the half bridge arrangement coupled to the outer (i.e. highest magnitude) bipolar voltage supply rail (item 220 of FIG. 2) is simply replaced with another copy of the same base transistor arrangement (item 310 in FIG. 3). This is to say, it uses another drain coupled pair of transistors (i.e. one drive transistor, and one additional switched transistor arranged as a bidirectional load switch), rather than single drive transistor, for the most positive/negative rail. The benefit of this arrangement is that it removes the limitation of the outer supply voltage (V_{P1}/V_{N1}, in FIG. 3) having to remain of greater magnitude than the inner ones (e.g. V_{P2}/V_{N2} in FIG. 3). This is because all transistors are protected by an additional switched transistor arranged as a bipolar load switch, so it is more robust, but at the expense of extra components. This is the say, in the example of FIG. 3, V_{P1} can go below V_{P2}, without damaging the drive transistor.

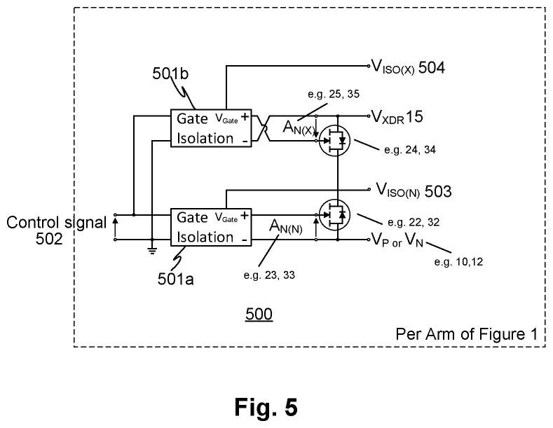

FIG. 4 shows an example circuit schematic diagram of an all PMOS arrangement 400 of a multilevel ultrasound transmitter according to an embodiment of the present disclosure. In this example, essentially all of the transistors get replaced by PMOS and in the process the positive/negative rails swap. This may be of use in circumstances needing a different drive voltage arrangement, and for example in particular where the capability (e.g. current handling, switching speed, etc) of a given sort of P-type transistor device is not an issue (or at least not worse that the N-type version). As shown in FIG. 4, where PMOS is used instead of NMOS (or more generically, any P-type devices instead of N-type devices), all the voltages and diode actions reverse—e.g. the circled arrow for the gate control voltage 402 is in the reverse direction compared to the arrow at the same point in FIG. 3. Similar goes for the diode directions as circled by 404. Also, compared to FIG. 2 where the source of device 206 is connected to the output V_{XDR} and the source of device 208 to the negative supply rail V_{N1}, in FIG. 4, these have reversed (i.e. the gate input to device 406 is referenced to V_{P1}, not V_{XDR}, and gate input to device 408 is referenced to V_{XDR}, not V_{N1}, and is as if V_{N1} and V_{P1} have swapped).

Conduction of each transistor in FIG. 1 is enabled or disabled by an associated gate drive voltage, 23, 25, 33, 35, typically referenced to the source of the respective transistor, which may be the single output V_{XDR}, 15, or one of the bipolar voltage supply rails, or other connection. Typical control electronics may be referenced to ground and, in which case, may implement some form of level shifting or gate isolation to control the transistors, 22, 24, 32, 34.

FIG. 5 discloses an example circuit schematic diagram of gate drive circuitry 500 for use, per arm (of FIG. 1), in a multilevel ultrasound transmitter according to an NMOS embodiment of the present disclosure. Note, a PMOS example would be essentially the same, but with + and − signals from the isolation blocks swapped.

The circuitry 500 of FIG. 5 is an example connection using gate isolation devices, 501a, 501b, such as a digital isolator or opto-coupler, whereby each arm may be switched together using the same control signal, 502 (however other examples may be switched individually). The gate isolation devices 501a/b may use a floating power supply V_{ISO(N)} 503, V_{ISO(X)} 504, used as input to the respective V Gate input of each isolation circuit, which could be provided by an isolated DC-DC converter or other means. Gate drive voltages, 25, 35 are referenced to the same common output, V_{XDR} 15, may share the same isolated power supply or multi-channel gate isolator, or may use individual circuitry. Meanwhile, gate drive voltages 23, 33 are referenced to the respective bipolar voltage supply rail instance (V_{P} or V_{N}).

Accordingly, FIG. 5 shows an example of suitable drive circuitry for each arm of FIG. 1. Thus, multiple instances of the circuitry of FIG. 5 may be provided, e.g. two for each extra instance of FIG. 1 involved (one per arm).

The disclosed multilevel switched-mode ultrasound transmitter topology, using GaN FET technology, allows for the removal of diodes in the standard half-bridge multilevel transmitter design, to thereby allow for lower losses and full push-pull capability to all bipolar voltage supply rails. Examples of the disclosed multilevel switched-mode ultrasound transmitter topology may replace all of the PMOS transistors with NMOS transistors to allow the use of GaN FET technology. As a direct drive topology, the disclosed multilevel switched-mode ultrasound transmitter topology can work over a wide range of frequencies as transformers or filters are not required.

A test structure implementation of the topology has been developed, occupying a small 25×25 mm area, in a layout which could be scaled up to much higher channel counts for research platforms and imaging systems. The disclosed multilevel switched-mode ultrasound transmitter has been demonstrated as capable of generating a wide range of transmit waveform options (up to an arbitrary number of output voltage levels, owing to the simple modular design) and switching speeds up to 100 MHz, whilst also providing high output power handling capabilities.

At diagnostic frequencies, the disclosed multilevel switched-mode ultrasound transmitter is capable of generating high quality HRPWM output waveforms, which show linear amplitude control over a wide range of frequencies, whilst showing well controlled second harmonics lending the design to harmonic imaging techniques. The power handling capabilities of the transmitter along with amplitude control capability allows it to operate in CW modalities and support HIFU therapy applications. For HFUS applications, the disclosed multilevel switched-mode ultrasound transmitter has been demonstrated as able to produce both wide bandwidth chirp and pseudo-gaussian waveforms, along with bipolar tones for high frequency imaging, whilst both positive and negative unipolar pulses could also be generated using any of the four supply rails in conjunction with the ground rail.

Examples provide a multilevel switched-mode ultrasound transmitter comprising a first push-pull transistor arrangement, the first push-pull transistor arrangement comprising first and second drive transistors, and third and fourth additional switched transistors, each of the third and fourth additional switched transistors being arranged as a bidirectional load switch with a one of the first and second drive transistors. In examples, the first drive transistor and associated third additional switched transistor operate in series as a first arm of the first push-pull transistor arrangement, and the second drive transistor and associated fourth additional switched transistor operate in series as a second arm of the first push-pull transistor arrangement, wherein each arm is coupled between a respective polarity instance of a first bipolar drive voltage supply and a common output (V_{XDR}).

In some examples, the first bipolar drive voltage supply comprises a positive supply voltage V_{P1} and a negative supply voltage V_{N1}. In some examples, the polarity instance of a first bipolar drive voltage supply is descriptive of whether the respective bipolar drive voltage supply is positive or negative. That is to say, for the first drive transistor, the respective polarity instance of a first bipolar drive voltage supply is the positive bipolar drive voltage V_{P1}, and for the second drive transistor, the respective polarity instance of a first bipolar drive voltage supply is the negative bipolar drive voltage V_{N1}.

Some examples of the disclosed multilevel switched-mode ultrasound transmitter may further comprise a single ended transistor clamp arrangement coupled between the common output and ground, wherein the single ended transistor clamp arrangement comprises a fifth drive transistor in series with a sixth additional switched transistor arranged as a bidirectional load switch. In some examples, the single ended transistor clamp arrangement is a ground clamp, and may have alternative circuitry to achieve the same effect of clamping the common output to ground by any other means.

Some examples may comprise a second push-pull transistor arrangement comprising seventh and eighth drive transistors, each coupled between a respective polarity instance of a (further) second bipolar drive voltage supply, wherein the second bipolar drive voltage supply is different to the first bipolar drive voltage supply. In some example, the second bipolar drive voltage supply is greater magnitude than the first bipolar drive voltage supply.

Some examples (with or without the second push pull arrangement) may comprise one or more further push-pull transistor arrangements, each comprising a further instance of the first push-pull transistor arrangement, and wherein each further push-pull transistor arrangement operates across a further bipolar drive voltage supply.

Some examples further comprise one or more further arms of further push-pull transistor arrangements (e.g. only a top or bottom arm of FIG. 1), each arm comprising a further instance of a drive transistor coupled in series with an additional switched transistor operating a bidirectional load switch, and wherein each further arm is coupled between a further polarity instance of a further bipolar drive voltage supply and the common output.

According to examples, each arm provides an additional operational voltage level for the multilevel switched mode ultrasound transmitter, such that an ultrasound transmitter capable of using any number of voltage levels may be provided. A minimum number of levels may be three, which may include a ground voltage level. A more typical arrangement may use 5 levels.

According to examples, each further bipolar drive voltage supply has a lower magnitude than a previous voltage supply, such that the overall relationships between the bipolar voltage supplies used (wherein each further bipolar drive voltage supply comprises a positive supply voltage V_{P1} and a negative supply voltage V_{Ni}) satisfy the following: V_{P1}>[V_{P2}, . . . V_{Pi}]>GND, and V_{N1}<[V_{N2}, . . . V_{Ni}]<GND.

In some examples, the bidirectional load switches are arranged in reverse polarity to a diode function of the respective drive transistors, where the ‘diode function’ may also be referred to as the ‘(intrinsic) body diode’, ‘parasitic diode’, or even the ‘diode like behaviour seen in some transistor types’ (e.g. GaN). In examples, the bidirectional load switches are arranged in reverse polarity to a diode function of the respective drive transistors, which may also be referenced as the two transistors are in anti-series.

In examples, a voltage to control a gate of any of the drive transistors is relative to a respective polarity instance of a respective bipolar drive voltage supply or a common output, where the term respective is used here (and everywhere else) to mean the instance of the item in question that relates to that specific part of the circuit (i.e. the common English usage of the term respective).

In some examples, a voltage to control a gate of any of the additional switched transistors is relative to the respective bipolar drive voltage supply or the common output.

In some examples, all the transistors are N channel devices (NPN (or N-Channel FET)).

In some examples, all the transistors are P channel devices (PNP (or P-Channel FET)).

In some examples, all the transistors are high mobility devices.

In some examples, all the high mobility devices comprise GaN devices.

In some examples, all the transistors are identical, i.e. the circuit is constructed out of multiple instances of the same base transistor device.

In some examples, the control circuitry operates a RTZ functionality to drive respective ultrasound transducers.

Examples also provide an ultrasound device comprising a transmitter according to any of any of the previous examples, and at least one ultrasound transducer, coupled to the transmitter.

Examples also provide a unified ultrasound architecture that provides both high power and high frequency operation, and therefore provides a single simplified circuit for operating ultrasound functions. Example ultrasound transmitters according to the present disclosure may be implemented to provide any number of voltage levels, by using multiple instances of the same basic per arm structure described herein.

There now follows alternatively worded descriptions of the same structural features as described in the previous examples, as applicable to a five level multilevel transmitter circuit, for example as shown in FIG. 3. Note, the use of terms ‘first’, ‘second’, etc is arbitrary in the following, and is not necessarily aligned to their use previously.

Examples also provide a transmitter drive circuit comprising: a first stage, comprising first and second NMOS devices arranged in a half-bridge topology, the first stage driven by a first bipolar voltage source, wherein a gate of the first NMOS device is referenced to an output node of the drive circuit, and a gate of the second NMOS device is referenced to a fixed voltage supply; a second stage, comprising third, fourth, fifth and sixth NMOS devices, wherein a gate of each of the third and sixth NMOS devices is referenced to a fixed voltage supply, and a gate of each of the fourth and fifth NMOS devices is referenced to the output node of the drive circuit; wherein the second stage is driven by a second bipolar voltage source, wherein the voltage of the second bipolar voltage source has a lower magnitude than the voltage of the first bipolar voltage source; and a third stage, comprising two NMOS devices arranged in a ground clamp topology.

Examples also provide a transmitter drive circuit comprising: an output node (V_{XDR}); a bipolar outer voltage rail; at least one bipolar mid voltage rail, wherein a voltage range of the bipolar mid voltage rail is of a lesser magnitude than a voltage range of the bipolar outer voltage rail; a ground rail; an outer stage, wherein the outer stage comprises a first NMOS device coupled between a positive rail of the bipolar outer voltage rail and the output node, and a second NMOS device coupled between a negative rail of the bipolar outer voltage rail and the output node, wherein a gate of the first NMOS device is referenced to the output node, and a gate of the second NMOS device is referenced to the negative rail of the bipolar outer voltage rail; at least one mid stage, wherein each mid stage comprises: a third NMOS device and a fourth NMOS device coupled in series between a positive rail of the at least one bipolar mid voltage rail and the output node, wherein the drains of the third NMOS device and the fourth NMOS device are coupled together, and a fifth NMOS device and a sixth NMOS device coupled in series between the output node and a negative rail of the at least one bipolar mid voltage rail, wherein the drains of the fifth NMOS device and the sixth NMOS device are coupled together, wherein a gate of each of the fourth and fifth NMOS devices is referenced to the output node, a gate of the third NMOS device is referenced to the positive rail of the at least one bipolar mid voltage rail, and a gate of the sixth NMOS device is referenced to the negative rail of the at least one bipolar mid voltage rail; and a ground clamp stage, wherein the ground clamp stage comprises a seventh NMOS device and an eighth NMOS device coupled in series between the output node and a negative rail of the at least one bipolar mid voltage rail, wherein the drains of the seventh NMOS device and the eighth NMOS device are coupled together, and wherein a gate of the seventh NMOS device is referenced to the output node, and a gate of the eighth NMOS device is referenced to the ground rail.

Examples of the present disclosure provide structural improvements to ultrasound transmitter designs that may be used in addition to (or potentially even instead of) HRPWM techniques, and provide these improvements by way of improving the symmetricity of the transmitter designs, so that the resultant transmitter operates substantially equally on both the positive and negative arms of the one or more bipolar voltage supplies used. Accordingly, examples of the disclosed transmitter circuit designs provide outputs that are more faithful to the ideal waveforms desired. This is because the disclosed example transmitter circuit design(s) may reuse multiple instances of the same transistor types (e.g. N-type vs P-type), hence simplifying the overall design and leveraging any improvements in one design type (e.g. in N-type) over the other (e.g. P-type) for any given transistor manufacturing process used (e.g. better conduction, charge carrier mobility, switching speed, etc.), and provide the aforementioned symmetrical performance of the overall design.

All of the features disclosed in this specification (including any accompanying claims, abstract, and drawings) may be combined in any combination, except combinations where some features are mutually exclusive. Each feature disclosed in this specification, including any accompanying claims, abstract, and drawings, may be replaced by alternative features serving the same, equivalent, or similar purpose, unless expressly stated otherwise. Thus, unless expressly stated otherwise, each feature disclosed in one example may be used with any other example provided herein.

The present teachings are not restricted to the specific details of any of the foregoing examples. Any novel combination of the features disclosed in this specification (including any accompanying claims, abstract, and drawings) is envisaged. The claims should not be construed to cover merely the foregoing examples, but also any variants which fall within the scope of the claims.

What is claimed is:

1. A multilevel switched-mode ultrasound transmitter comprising:
a first push-pull transistor arrangement comprising:
first and second drive transistors;
third and fourth additional switched transistors, each arranged as a bidirectional load switch with a one of the first and second drive transistors;
wherein the first drive transistor and associated third additional switched transistor operate in series as a first arm of the first push-pull transistor arrangement, and the second drive transistor and associated fourth additional switched transistor operate in series as a second arm of the first push-pull transistor arrangement, wherein each arm is coupled between a respective polarity instance of a first bipolar drive voltage supply and a common output.

2. The multilevel switched-mode ultrasound transmitter of claim 1, further comprising:
a single ended transistor clamp arrangement coupled between the common output and ground, wherein the single ended transistor clamp arrangement comprises a fifth drive transistor in series with a sixth additional switched transistor arranged as a bidirectional load switch.

3. The multilevel switched-mode ultrasound transmitter of claim 1, further comprising a second push-pull transistor arrangement comprising:
seventh and eighth drive transistors, each coupled between a respective polarity instance of a second bipolar drive voltage supply, wherein the second bipolar drive voltage supply is greater magnitude than the first bipolar drive voltage supply.

4. The multilevel switched-mode ultrasound transmitter of claim 1, further comprising one or more further push-pull transistor arrangements, each comprising a further instance of the first push-pull transistor arrangement, and wherein each further push-pull transistor arrangement operates across a further bipolar drive voltage supply.

5. The multilevel switched-mode ultrasound transmitter of claim 4, wherein each further bipolar drive voltage supply has a lower magnitude than a previous bipolar drive voltage supply.

6. The multilevel switched-mode ultrasound transmitter of claim 1, wherein the bidirectional load switches are arranged in reverse polarity to a diode function of the respective drive transistors.

7. The multilevel switched-mode ultrasound transmitter of claim 1, wherein a voltage to control a gate of any of the additional switched transistors is relative to the common output.

8. The multilevel switched-mode ultrasound transmitter of claim 1, wherein all the transistors are N channel devices (NPN (or N-Channel FET)).

9. The multilevel switched-mode ultrasound transmitter of claim 1, wherein all transistors are high mobility devices.

10. The multilevel switched-mode ultrasound transmitter of claim 1, wherein all transistors are GaN devices.

11. The multilevel switched-mode ultrasound transmitter of claim 1, wherein the transmitter has at least three voltage levels.

12. An ultrasound device comprising:
a transmitter according to claim 1;
at least one ultrasound transducer, coupled to the transmitter.
